(19) United States
(12) Patent Application Publication
(10) Pub. No.: US 2010/0104043 A1
(43) Pub. Date: Apr. 29, 2010

(54) POWER AMPLIFIER

(76) Inventors: Ronan Farrell, County Kildare (IE); Stephen Ralph, Carlow (IE)

Correspondence Address: JACOBSON HOLMAN PLLC, 400 SEVENTH STREET N.W., SUITE 600, WASHINGTON, DC, 20004, US

(21) Appl. No.: 12/450,333

(22) PCT Filed: Mar. 19, 2008
(86) PCT No.: PCT/IE2008/000025

§ 371 Date: Sep. 22, 2009

(30) Foreign Application Priority Data
Mar. 22, 2007 (IE) 2007/0195

(51) Int. Cl. H04L 25/49; H03F 3/217; H04B 1/04

(52) U.S. Cl. 375/296; 330/251; 455/114.3

(57) ABSTRACT

A switched mode class-S power amplifier comprises a sigma-delta modulator with a digital input, a power switch connected to the output of the sigma-delta modulator providing the power amplifier output, and a feedback mechanism. The sigma-delta modulator has a high-pass transfer function and uses an offset switching frequency to remove an unwanted image over half of the switching frequency. The amplifier may have a filter to remove unwanted fold-over image. There may be at least two modulators arranged in parallel, and there may be a complex filter for constructively combining the modulator outputs.

### INTRODUCTION

The invention relates to power amplifiers such as high frequency power amplifiers for wireless transmitters.

A typical wireless transmitter comprises a digital processor or software section, a digital-to-analog converter (DAC) (to convert it to an analog voltage), a filter (to remove noise), a mixer (to move it to the right frequency), a power amplifier (to give it power so it can travel), another filter (to remove noise at this stage) and an antenna. This is illustrated in FIG. 1. The more stages in the transmitter, the more expensive it is to build, the poorer the performance and the more noise that is added that needs to be filtered.

There are several approaches to simplify this architecture including:
to make the DAC fast enough, to avoid need for a mixer
to make the DAC fast enough, and with enough power, to avoid need for a mixer or a PA

In the second approach, the DAC can take a digital signal and produce an RF output. The most promising approach to date is that of sigma-delta modulator based DACs. In these, a pair of switches turns the output on/off in a pattern that produces the output. This works well for low frequencies and is used in most high quality audio systems.

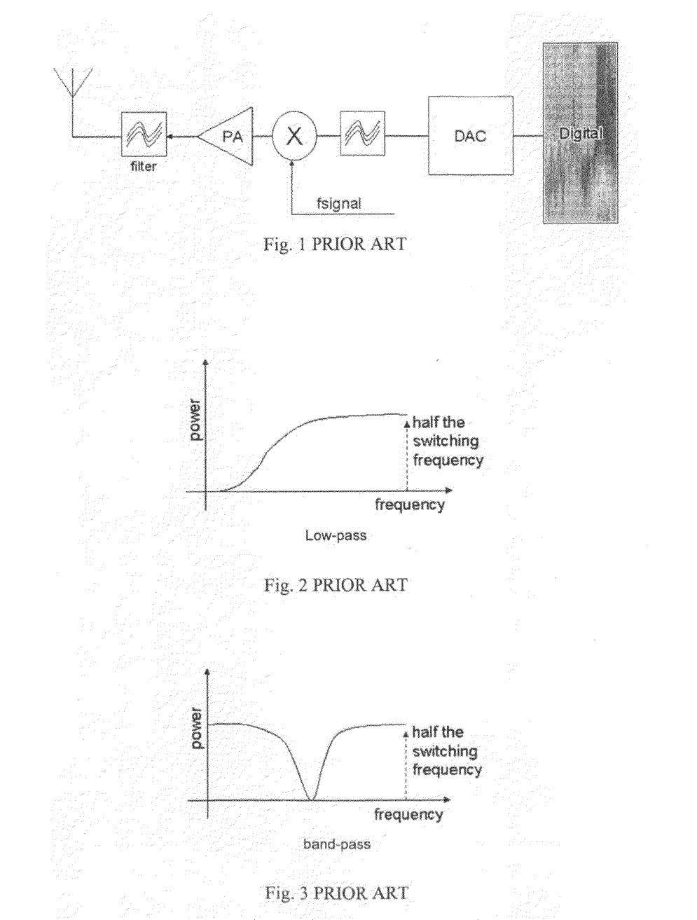

One form of power amplifier utilises digitally controlled switches where the power is switched on and off in a pattern that results in a modulated signal. This general approach has been called a class-D amplifier and typically uses a sigma-delta modulator to generate the appropriate pattern of bits. This has been widely used for low-frequency applications, for example audio applications (FIG. 2).

Referring to FIG. 3, for RF applications a particular form of sigma-delta modulator called a band-pass sigma-delta modulator is used. This provides a noise notch in the band of interest and allows the desired signal to pass noise-free. When used in this mode, the amplifier is then typically called a Class-S PA. This notch in the noise is adjustable, but typically occurs at ¼ the switching frequency for ease of implementation.

Proposed architectures for class-S power amplifiers to date have focussed on accepting analog input signals, using the sigma-delta modulator to convert this signal to a binary bitstream which is then used to control the power switches. This provides compatibility with existing amplifier architectures.

The benefits of class-S power amplifiers are:
superior power amplifier efficiencies
high linearity
superior cost-benefit performance to other DACs

However the problems with this approach are that:
The modulator in the PA must operate at 4 times the frequency of the output signal, which means for a 3G system at 2.1 GHz, the digital logic and the analog circuits operate at 8.4 GHz. This is not conveniently possible and consumes significant power
The switches required to switch the power are not available at this frequency with the required power levels.
It is possible to operate at a harmonic of the ¼ fs frequency, but this inherently incurs a significantly reduced signal-to-noise ratio, and reduced power efficiency.
Using analog input signals for the modulator requires additional stages prior to the amplifier to convert the signal into an appropriate analog signal, and limits the capability of the amplifier modulator.
Power switches are inherently non-linear and this is a major challenge in wireless communications. Normally feedback mechanisms would be used to correct for these non-linearities however in existing class-S architectures, there is no convenient mechanism to implement this.
The use of analog input signals requires preceding analog circuits and makes integration with the digital systems difficult.

The invention is therefore directed towards providing an improved architecture for power amplifiers particularly for high frequency applications such as found in wireless and wired communications.

### STATEMENTS OF INVENTION

According to the invention, there is provided a switched mode class-S power amplifier comprising a sigma-delta modulator with a digital input, a power switch connected to the output of the sigma-delta modulator providing the power amplifier output, and a feedback mechanism.

In one embodiment, the sigma-delta modulator has a high-pass transfer function.

In one embodiment, the sigma-delta modulator uses an offset switching frequency to remove an unwanted image over half of the switching frequency.

In one embodiment, the amplifier further comprises a filter to remove unwanted fold-over image.

In one embodiment, the modulator comprises means for accepting digital data input and utilises an internal all-digital modulator stage.

In one embodiment, the feedback mechanism comprises means for feeding back distortion measurements to a digital processing unit prior to the modulator stage.

In one embodiment, the modulator has a band-pass or a low-pass transfer function, and the amplifier further comprises a frequency shifter for post-processing the modulator output to map the modulator transfer function to that of an equivalent high-pass transfer function.

In one embodiment, the amplifier comprises means for providing parallel outputs from the sigma-delta modulator.

In one embodiment, the outputs are generated by components for parallel processing of the modulator output.

In one embodiment, the amplifier comprises at least two modulators arranged in parallel.

In one embodiment, the amplifier further comprises a complex filter for constructively combining the modulator outputs.

In one embodiment, the modulators comprise a complex transfer function internally to induce a phase inversion for constructively combining the modulator outputs

In one embodiment, the amplifier further comprises a multiplexer for delivering multiplexed modulator outputs to the power switches.

In one embodiment, the amplifier further comprises means for updating each modulator with internal variables according to a predictive scheme.

In one embodiment, the predictive scheme calculates the next output once the previous values of u, v, and the current input x are known.

In one embodiment, the modulators are different and each modulator produces the appropriate output, based on initial conditions, for a certain number of steps ahead, and the amplifier comprises means for up updating all modulators after each cycle with a final value of internal variables.

In one embodiment, the modulators incorporate integral complex filters to undertake a phase shift for purposes of image cancellation.

In another aspect, the invention provides an RF transmitter comprising any power amplifier as defined above, a filter at the output of the power amplifier, and an antenna at the output of the filter.

In one embodiment, the transmitter comprises an RF signal combiner to combine signals to cancel an unwanted image.

### DETAILED DESCRIPTION OF THE INVENTION

The invention will be more clearly understood from the following description of some embodiments thereof, given by way of example only with reference to the accompanying drawings in which:—

FIGS. 1 to 3 relate to the prior art as set out above;

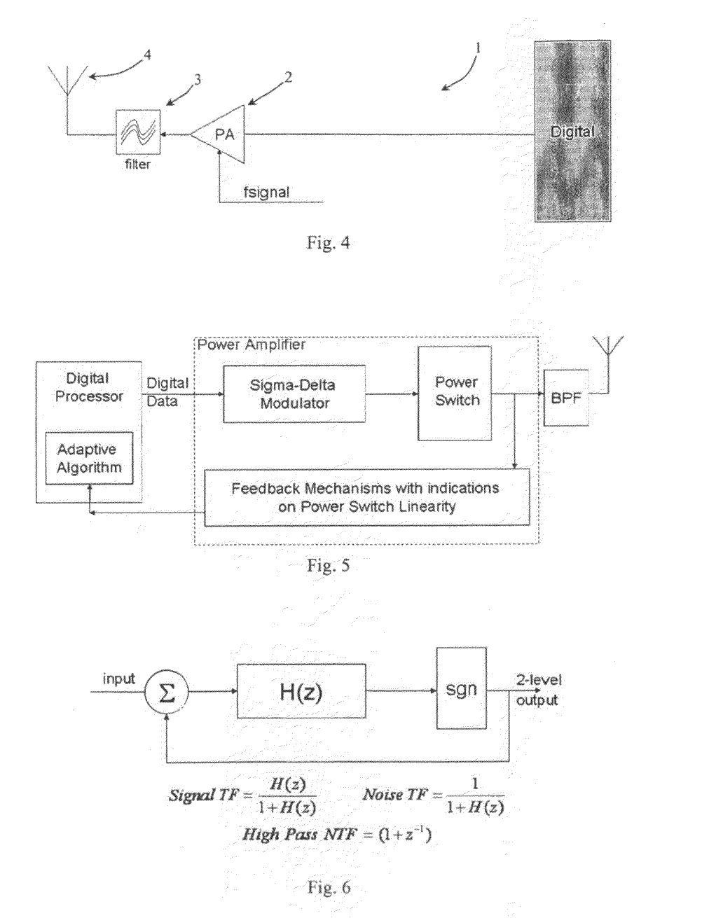

FIG. 4 is a high level block diagram of a transmitter utilising a power amplifier of the invention;

FIG. 5 is a more detailed diagram of the transmitter;

FIG. 6 is a block diagram of a sigma-delta modulator of the transmitter in the digital domain, with expressions for the signal and noise transfer functions;

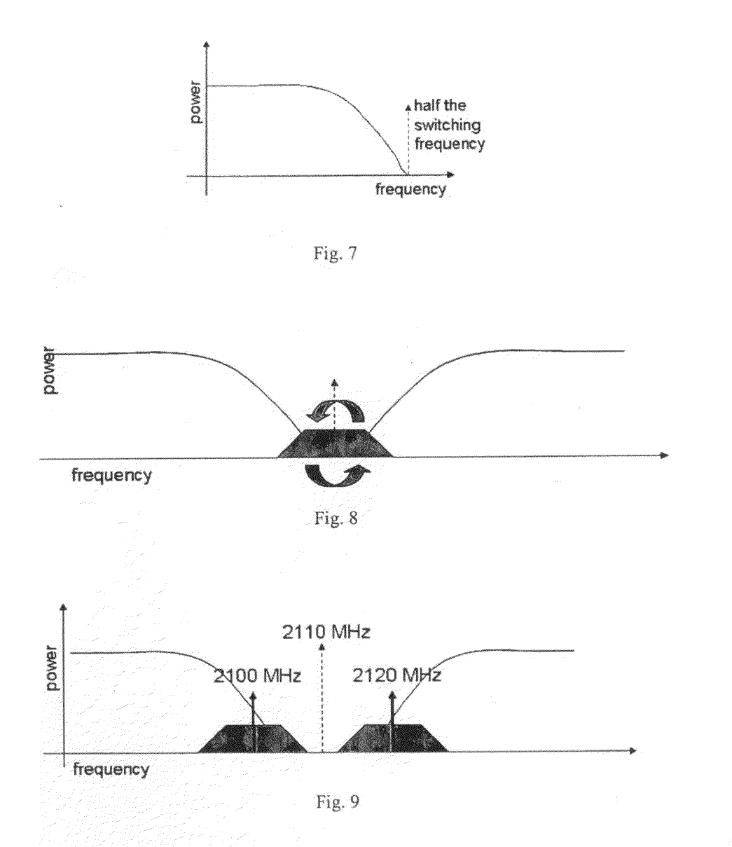

FIG. 7 is an illustrative plot showing a possible output spectrum of the power amplifier using a high-pass sigma-delta modulator;

FIGS. 8 and 9 are plots illustrating aspects of operation of the power amplifier showing the possible locations of frequency components for the high-pass sigma-delta modulator;

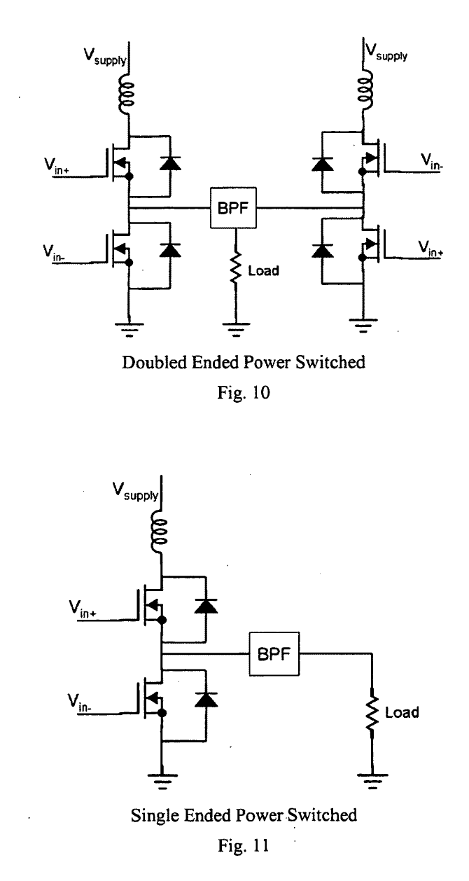

FIGS. 10 and 11 are diagrams of two possible circuit designs for the power switches of the amplifier;

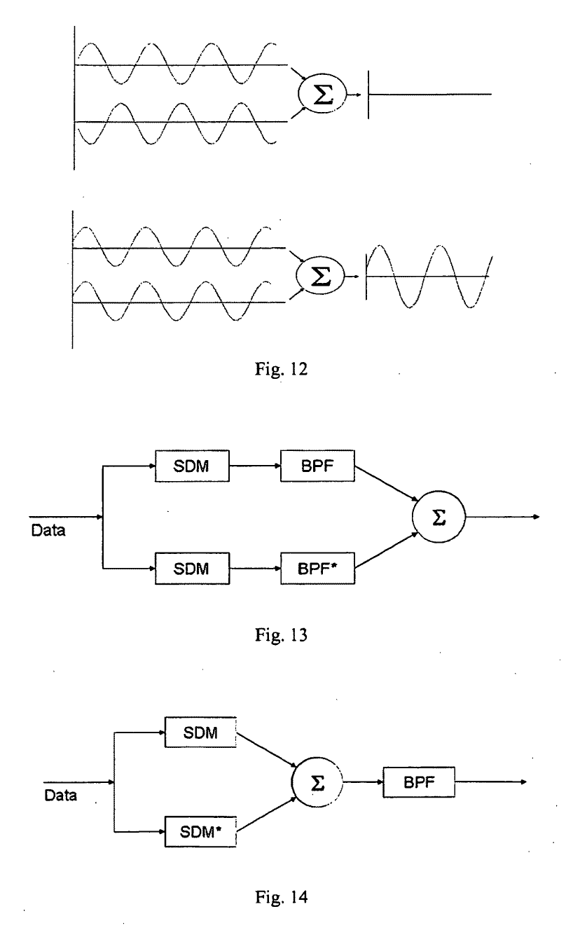

FIG. 12 is a pair of diagrams illustrating constructive and destructive combination of sinusoids;

FIGS. 13 and 14 are illustrative diagrams showing architectures for the power amplifier using either a filter or a sigma-delta modulator with a complex transfer function so as to cancel unwanted spectral components;

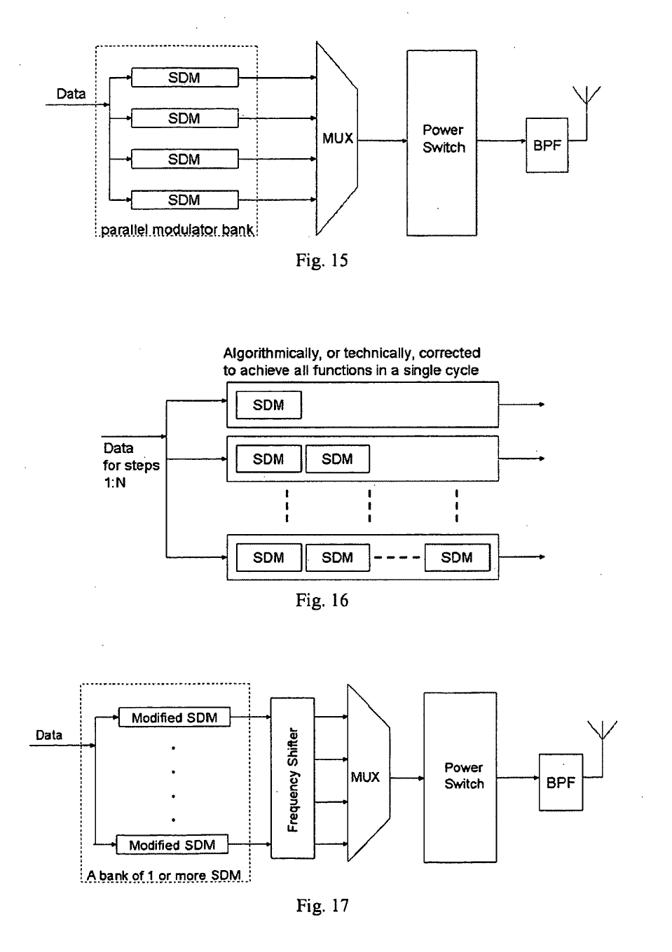

FIG. 15 shows a power amplifier with a parallel modulator bank;

FIG. 16 is a diagram illustrating the function of modified parallelised sigma-delta modulators;

FIG. 17 is a diagram showing the inclusion of a frequency shifter which can be used with one or more sigma-delta modulators (both modified and unmodified) to implement a parallel sigma-delta modulators with the ability to translate the signal pass band from one part of the spectrum to another;

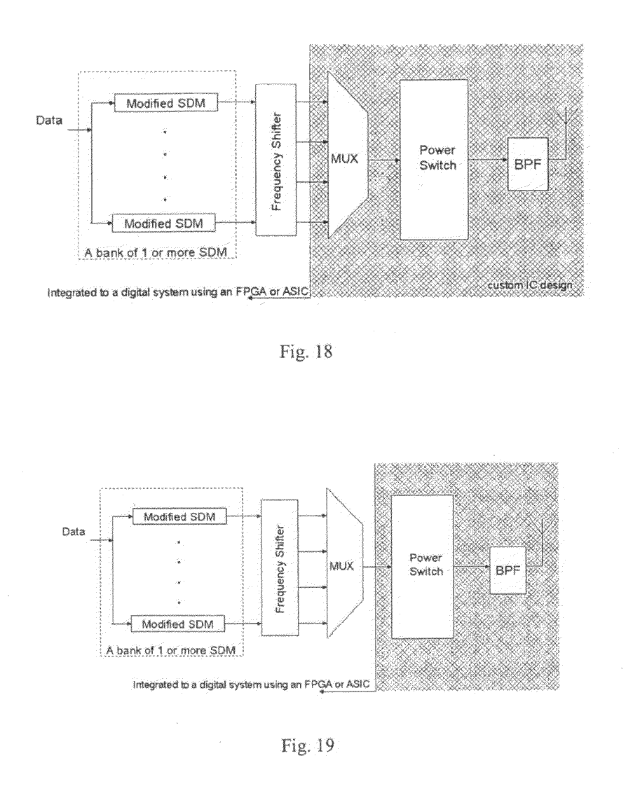

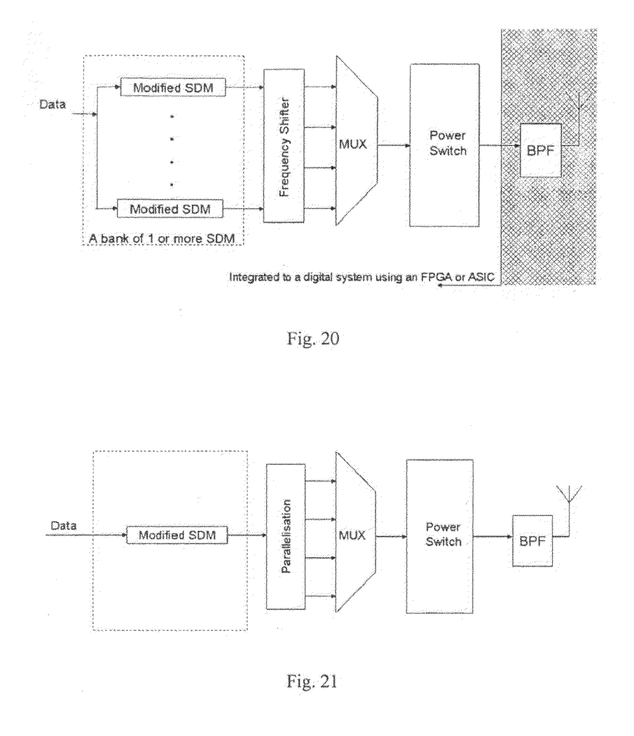

FIGS. 18 to 20 are diagrams showing alternative implementations with different levels of integration with a digital system, for example an FPGA, according to the partitioning of the power amplifier components between the analog and digital domains; and

FIG. 21 shows a sigma-delta modulator whose output is subsequently processed to produce a parallelised output.

Referring to FIGS. 4 and 5 a transmitter 1 of the invention comprises a power amplifier 2, a filter 3, and an antenna 4. The power amplifier (“PA”) is fed directly by an (external) digital processor, and so the transmitter 1 has few components. In more detail, the transmitter comprises a sigma-delta modulator, power switches, filters, a digital processing unit (e.g. computer, FPGA) and a mechanism for correcting for non-linear distortion.

Referring to FIG. 6, the sigma delta modulator has a high pass transfer function where the signal pass band is close to half the switching rate, as illustrated in FIGS. 7 and 8. An expression is provided in FIG. 6 for the simplest form of high-pass sigma-delta modulator, though more complex functions are possible and desirable. The modulator also comprises a switched power stage capable of switching between ground and the supply voltage on the basis of a binary digital input, and a mechanism for measuring distortion and feeding this information back to the digital processing unit. Examples of a single and double ended power switch are shown in FIGS. 10 and 11.

The digital input from the digital processing unit to the amplifier stage allows the amplifier to implement the modulator in a purely digital manner. This avoids the power and implementation difficulties of existing amplifier structures where the modulator uses an analog input stage. FIGS. 18 to 20 show possible partitions for the power amplifier between digital and analog components the blocks in the shaded portion being analog. The use of digital input to produce an analog (RF) output also means that this modified class-S amplifier could be considered as a digital-to-analog converter.

The output of the PA is switched, which means that the transmitter must take into consideration the effect of switching and the harmonic distortion this causes. As shown in FIG. 7, what is above fs/2 is a mirror image of what was below. A signal centred at fs/2 will fold in on top of itself, corrupting the signal. For this reason, the prior approach was not to use high-pass modulators for DAC purposes.

However, in the invention it is possible to use the high-pass modulator for communications purposes as it uses an offset-switching frequency. Typically, in a band-pass modulator, to generate a signal frequency of 2.1 GHz, a switching frequency of 8.4 GHz is required. For the equivalent high-pass modulator, the switching frequency would be 4.2 GHz. However with an input signal coming into the amplifier at 2.1 GHz there is a switching frequency of 4.22 GHz (20 MHz too high). In this case the input signal does not map onto itself and it is possible to design a suitable band-pass filter (BPF) to remove the unwanted image. Band-pass filters are present in all transmitter architectures (FIG. 4) to prevent extraneous signals from being transmitted. Using offset frequency and the simplest implementation of the sigma-delta modulator means that the signal of interest is no longer at the section of the spectrum with the greatest noise rejection and thus there is the potential for increased noise (FIG. 8). However the technique for modifying the signal-transfer function shown in FIG. 7 is such that the noise rejection performance of the modulator in the amplifier can be restored (FIG. 8).

Thus, the PA 2 uses a high-pass modulator, resulting in the following benefits over the prior band-pass architecture:—
Reduces the switching frequency by almost 50%, enabling existing technology to be used to implement this approach.
The high-pass modulator is over 50% smaller than the equivalent band-pass structure.
Total power consumption in the modulator could be up to 8 times less than that of the equivalent band-pass structure.

The PA 2 has an additional clock signal generator than the one used for the receiver. The receiver picks up signals at, for example, 2.1 GHz (normally divided down from 4.2) whereas the one for transmission is at 4.22 MHz. However the transmission frequency is often different from the receive frequency so this is not an excessive consideration (examples include 2G, 3G, WiMAX). In other implementations it may be more convenient to superimpose the image onto the receive band. Some communication protocols are robust to strong in-band blockers and a more optimal implementation may take advantage of this feature where available.

Power amplifiers, and especially switched mode power amplifiers, are vulnerable to non-linear transfer characteristics. In the invention, any distortion that is detected is fed directly back to the digital processing unit where appropriate algorithms can be implemented and the signal data corrected in advance to be sent to the amplifier. This allows for more computationally complex algorithms to be implemented and can avail of the superior granularity of correction that digital computation allows.

There are many techniques for characterising the linearity of an amplifier transfer function. An example of a technique that would be applicable to this implementation would be to take a measure of the signal power (or amplitude) through means of a monitoring circuit. Normally this measurement is an analog measurement and the architecture will need to be converted to a digital representation through use of an analog-to-digital converter (ADC). The signal power can then be compared to what was expected, and appropriate correction factors computed. These correction factors can then be applied to the signal data prior to being sent to the power amplifier block. Other characteristics of the amplifier output may also be used, singly or in combination, to produce an appropriate feedback signal.

### Image Above Fs/2

The high-pass sigma-delta modulator suffers from the presence of an image above half the switching frequency (fs/2). This image can be shifted through offsetting to place it at a frequency at which it does not cause interference or may be filtered out. It is desirable to remove this unwanted image.

The power amplifier can use a technique whereby it takes advantage of an RF signal combiner in the transmitter chain to combine two specially created signals such that the unwanted image is cancelled. Power combiners are common in high power radio transmitters (such as found in basestations) as they allow the transmitter to combine multiple power amplifiers into one effective amplifier. In case of failure of an amplifier, the transmitter experiences reduced performance rather than total failure.

When two sine waves which are 180° out of phase with each other are added together, the net result is zero, as shown in FIG. 11 top diagram. However when they are in phase they combine constructively, and double in size, as shown in FIG. 12 bottom diagram.

As shown in FIG. 13, it is possible through the use of complex filters (mathematical definition of complex as in having non-real, imaginary components) to have a filter such that the amplitude remains the same while inducing a 180 degree phase shift. If two sigma-delta modulators which were identical in all other respects had their outputs combined, then the effect would be to remove all frequencies that were not perfectly in-phase.

As the signal-transfer function of a sigma-delta modulator is directly related to the open-loop filter of the modulator, the complex transfer function required to induce the phase inversion may be incorporated into the modified sigma-delta modulator, thus simplifying further the transmitter architecture as shown in FIG. 14. This has the advantage of precise numerical computation as the SDM is implemented in the digital domain.

The modulator therefore removes the unwanted image through inducing a phase inversion in the output signal of a matched sigma-delta modulator.

An external filter achieves the needed phase shift, while in another embodiment a complex transfer function internally to the sigma-delta modulator is used.

### Parallelisation of the Sigma-Delta Modulator Using a Predictive Methodology

The sigma-delta modulator required for use in Class-S PA's needs to operate at the frequency of the switches: receiving high resolution data at that frequency; processing; and delivering the relevant sequence of ones and zeros. Digital circuits at these high frequencies are difficult to design and consume significant quantities of power. They are not easily integrated into normal digital processing units used in wireless communications.

One solution to this technique would be to use time-interleaved sigma-delta modulators to reduce the required operating frequency of the digital circuits. However existing topologies produce a multi-bit output which is incompatible with existing solutions.

Our structure takes advantage of the nature of the sigma-delta modulator and has a parallelised structure for creating the bit-stream signal. This signal can then be multiplexed into a high-speed serial bit stream for driving the power switches. An embodiment is shown in FIG. 15. In this embodiment a number of parallel sigma-delta modulators are shown to have their outputs combined to produce a high-speed serial output. This method cannot be directly applied in this application due to the need to preserve a single-bit output.

An architecture that can be used is to construct a parallel modulator bank in such a way that each modulator produces the appropriate output, based on some initial conditions and the appropriate data, for a certain number of steps ahead. In a sense, the first modulator in the bank produces the relevant output, and all subsequent modulators “look ahead” and produce the correct output, as illustrated in FIG. 16. After each cycle, all modulators will be updated with the final value of the internal variables. This is achievable as while sigma-delta modulators are non-linear dynamical systems with complex behaviour, they are deterministic, and future behaviour in a digital implementation can be predicted. The data signal provides the forward-looking data for the respective modulators. This approach may be used for any sigma-delta modulator transfer function, low-pass, band-pass and high-pass systems.

The behaviour of the second order low-pass sigma-delta modulator is given by the coupled line expression:

uₙ=xₙ+uₙ₋₁−sgn(vₙ₋₁)

vₙ=uₙ+vₙ₋₁−sgn(vₙ₋₁)
where uₙ and vₙ are the values stored on the first and second integrators respectively and xₙ is the current input value

This allows the calculation of the next output (at time n using the sgn function) once the previous values of u, v, and the current input x, are known. It is possible to extrapolate to the future in a simple algebraic form. An example of the output for the first step “looking ahead” is:

$$\begin{matrix}{u}_{n + 1} = {x}_{n + 1} + {u}_{n} - sgn ( {v}_{n} ) \\ = {x}_{n + 1} + ( {x}_{n} + {u}_{n - 1} - sgn ( {v}_{n - 1} ) ) - sgn ( {u}_{n} + {v}_{n - 1} - sgn ( {v}_{n - 1} ) ) \\ = ( {x}_{n + 1} + {x}_{n} ) + {u}_{n - 1} - [ \begin{matrix}sgn ( {v}_{n - 1} ) + \\ sgn ( \begin{matrix}{x}_{n} + {u}_{n - 1} - sgn ( {v}_{n - 1} ) + \\ {v}_{n - 1} - sgn ( {v}_{n - 1} )\end{matrix} )\end{matrix} ]\end{matrix}$$

$$\begin{matrix}{v}_{n + 1} = {u}_{n + 1} + {v}_{n} - sgn ( {v}_{n} ) \\ = ( {x}_{n + 1} + {x}_{n} ) + {u}_{n - 1} - [ \begin{matrix}sgn ( {v}_{n - 1} ) + \\ sgn ( \begin{matrix}{x}_{n} + {u}_{n - 1} - sgn ( {v}_{n - 1} ) + \\ {v}_{n - 1} - sgn ( {v}_{n - 1} )\end{matrix} )\end{matrix} ] + \\ ( {x}_{n} + {u}_{n - 1} - sgn ( {v}_{n - 1} ) ) + {v}_{n - 1} - sgn ( {v}_{n - 1} ) - \\ [ sgn ( {v}_{n - 1} ) + sgn ( \begin{matrix}{x}_{n} + {u}_{n - 1} - sgn ( {v}_{n - 1} ) + \\ {v}_{n - 1} - sgn ( {v}_{n - 1} )\end{matrix} ) ]\end{matrix}$$

While mathematically complex, the implementation of this function is straightforward and simple, thereby being amenable to implementation either in a DSP device or in an FPGA.

An alternative implementation of the high-pass sigma delta modulator may be achieved through the use of a frequency shifting operation which post-processes the output of the sigma-delta modulator. This operation can map the transfer function of either a low-pass or band-pass sigma-delta modulator to that of an equivalent high-pass system. Appropriate mapping functions can be derived mathematically through analysis of the sigma-delta modulator transfer function. It is also possible to extend the principle of parallelisation to this mapping function and achieve parallelisation of the outputs though using only a single sigma-delta modulator as shown in FIG. 21. This has the effect of both transfer function mapping and frequency multiplication. While not exactly the same process as parallelisation of the sigma-delta modulators, it has many of the same performance benefits. This approach can be extended to include multiple parallelised sigma-delta modulators feeding the frequency shifting unit as shown in FIG. 17.

Referring to FIG. 21, an alternative transmitter utilises parallelisation through processing the output of a single sigma-delta modulator. This processing can also introduce a frequency multiplication effect which can be used to manipulate the signal and noise transfer functions. While this has implications on spectral performance, it achieves many of the same performance benefits of parallelisation.

In summary, the invention in one aspect provides for parallelising a sigma-delta modulator to provide the appropriate sequence of 1-bit outputs while operating at an overall slower speed. It also achieves the reduction of the computational and power requirements in a class-S type power amplifier (whether using band-pass or high-pass modulators) through the parallel processing approach.

Existing Class-S amplifiers use analog inputs which are then internally modulated to produce the equivalent digital bitstream. This preserves compatibility with existing analog amplifiers in the prior art. The input to the amplifier of the invention is a multi-bit digital word allowing for the sigma-delta modulator, and associated elements, to be implemented fully in digital form.

Also there is a synergy between use of a high pass transfer function and parallel SDMs as both will increase the ratio of RF channel frequency to the digital modulator processing speed, making it easier to implement high frequency communication systems in available digital logic technology, such as FPGAs.

It will be appreciated that the invention allows for a significant reduction in the complexity of radio transmitters while providing superior performance. It is very advantageous to use an offset switching frequency to separate the signal image when using a high-pass transfer function. There would have been a technical prejudice against this as the DAC designer would not see the benefit of offsetting the input signal from the optimal location as it incurs degraded noise performance.

This invention allows the significant simplification of transmitter architectures. A transmitter of the invention uses fewer components and can be more tightly integrated. It can be more linear as each component causes distortion, it can have less noise as each component adds noise, and it can have higher electrical power efficiency as there are no analog components to introduce losses.

Also, the transmitter can be implemented with standard silicon technology, does not require further advancements in digital speed. The modulator of the invention will be many times less power hungry than equivalent band-pass technologies. Further, with lower switching speeds than band-pass systems, the efficiency and linearity of the system will be superior.

The invention is not limited to the embodiments described but may be varied in construction and detail.

1-19. (canceled)

20. A switched mode class-S power amplifier comprising a sigma-delta modulator with a digital input, a power switch connected to the output of the sigma-delta modulator providing the power amplifier output, and a feedback mechanism,
wherein the feedback mechanism comprises means for feeding back distortion measurements from the output of the power switch to a digital processing unit prior to the modulator,
wherein the modulator has a band-pass or a low-pass transfer function, and the amplifier further comprises a frequency shifter for post-processing the modulator output to map the modulator transfer function to that of an equivalent high-pass transfer function, and
wherein the power amplifier comprises means for providing parallel outputs from the sigma-delta modulator.

21. The power amplifier as claimed in claim 20, wherein the sigma-delta modulator has a high-pass transfer function.

22. The power amplifier as claimed in claim 20, wherein the sigma-delta modulator has a high-pass transfer function, and wherein the sigma-delta modulator uses an offset switching frequency to remove an unwanted image over half of the switching frequency.

23. The power amplifier as claimed in claim 20, wherein the sigma-delta modulator has a high-pass transfer function, and wherein the sigma-delta modulator uses an offset switching frequency to remove an unwanted image over half of the switching frequency; and wherein the amplifier further comprises a filter to remove unwanted fold-over image.

24. The power amplifier as claimed in claim 20, wherein the modulator comprises means for accepting digital data input and utilises an internal all-digital modulator stage.

25. The power amplifier as claimed in claim 20, whereby the outputs are generated by components for parallel processing of the modulator output.

26. The power amplifier as claimed in claim 20, comprising at least two modulators arranged in parallel.

27. The power amplifier as claimed in claim 20, comprising at least two modulators arranged in parallel; and further comprising a complex filter for constructively combining the modulator outputs.

28. The power amplifier as claimed in claim 20, comprising at least two modulators arranged in parallel; and further comprising a complex filter for constructively combining the modulator outputs; and wherein the modulators comprise a complex transfer function internally to induce a phase inversion for constructively combining the modulator outputs

29. The power amplifier as claimed in claim 20, comprising at least two modulators arranged in parallel; and further comprising a multiplexer for delivering multiplexed modulator outputs to the power switches.

30. The power amplifier as claimed in claim 20, comprising at least two modulators arranged in parallel; and further comprising means for updating each modulator with internal variables according to a predictive scheme.

31. The power amplifier as claimed in claim 20, comprising at least two modulators arranged in parallel; and further comprising means for updating each modulator with internal variables according to a predictive scheme; and wherein the predictive scheme calculates the next output once the previous values of u, v, and the current input x are known.

32. The power amplifier as claimed in claim 20, comprising at least two modulators arranged in parallel; and wherein the modulators are different and each modulator produces the appropriate output, based on initial conditions, for a certain number of steps ahead, and the amplifier comprises means for up updating all modulators after each cycle with a final value of internal variables.

33. The power amplifier as claimed in claim 20; comprising at least two modulators arranged in parallel; and wherein the modulators incorporate integral complex filters to undertake a phase shift for purposes of image cancellation.

34. An RF transmitter comprising:
a switched mode class-S power amplifier comprising a sigma-delta modulator with a digital input, a power switch connected to the output of the sigma-delta modulator providing the power amplifier output, and a feedback mechanism,
wherein the feedback mechanism comprises means for feeding back distortion measurements from the output of the power switch to a digital processing unit prior to the modulator,
wherein the modulator has a band-pass or a low-pass transfer function, and the amplifier further comprises a frequency shifter for post-processing the modulator output to map the modulator transfer function to that of an equivalent high-pass transfer function, and
wherein the power amplifier comprises means for providing parallel outputs from the sigma-delta modulator;
a filter at the output of the power amplifier, and
an antenna at the output of the filter.

35. The RF transmitter as claimed in claim 34, wherein the transmitter comprises an RF signal combiner to combine signals to cancel an unwanted image.
